(19) United States
(12) Patent Application Publication
(10) Pub. No.: US 2024/0431114 A1
(43) Pub. Date: Dec. 26, 2024

(54) FERROELECTRIC MEMORY DEVICE AND MANUFACTURING METHOD OF THE FERROELECTRIC MEMORY DEVICE

(71) Applicant: SK hynix Inc., Icheon-si Gyeonggi-do (KR)

(72) Inventor: Sunghyun Yoon, Icheon-si Gyeonggi-do (KR)

(73) Assignee: SK hynix Inc., Icheon-si Gyeonggi-do (KR)

(21) Appl. No.: 18/517,496

(22) Filed: Nov. 22, 2023

(30) Foreign Application Priority Data
Jun. 21, 2023 (KR) 10-2023-0079539

(51) Int. Cl. H10B 51/20; H10B 51/30

(52) U.S. Cl. CPC H10B 51/20; H10B 51/30

(57) ABSTRACT

A ferroelectric memory device, and a manufacturing method of the ferroelectric memory device, includes a gate stack structure including a plurality of interlayer insulating layers and a plurality of conductive layers, which are alternately stacked. The ferroelectric memory device also includes a channel layer extending in a vertical direction (the stacking direction) in the gate stack structure. The ferroelectric memory device further includes ferroelectric patterns interposed between the plurality of conductive layers and the channel layer. The ferroelectric memory device additionally includes anti-ferroelectric patterns interposed between the plurality of interlayer insulating layers and the channel layer.

### CROSS-REFERENCE TO RELATED APPLICATION

The present application claims priority under 35 U.S.C. § 119(a) to Korean patent application number 10-2023-0079539 filed on Jun. 21, 2023, in the Korean Intellectual Property Office, the entire disclosure of which is incorporated by reference herein.

### BACKGROUND

### 1. Technical Field

The present disclosure generally relates to an electronic device, and more particularly, to a ferroelectric memory device and a manufacturing method of the ferroelectric memory device.

### 2. Related Art

A memory device may be classified as a volatile memory device in which stored data disappears when the supply of power is interrupted or a nonvolatile memory device in which stored data is retained even when the supply of power is interrupted.

The nonvolatile memory device may include NAND flash memory, NOR flash memory, resistive random-access memory (ReRAM), phase-change random-access memory (PRAM), magnetoresistive random-access memory (MRAM), ferroelectric random-access memory (FRAM), spin transfer torque random-access memory (STT-RAM), and the like.

A ferroelectric memory device including ferroelectric random-access memory may store data, using a spontaneous polarization characteristic of a ferroelectric material. Therefore, the ferroelectric memory device may use a material having a ferroelectric characteristic as a data storage layer, and an electrical characteristic of the ferroelectric memory device may be changed according to the characteristic of the material used as the data storage layer.

### SUMMARY

In accordance with an embodiment of the present disclosure is a ferroelectric memory device including: a gate stack structure including a plurality of interlayer insulating layers and a plurality of conductive layers, which are alternately stacked; a channel layer extending in a vertical direction (the stacking direction) in the gate stack structure; ferroelectric patterns interposed between the plurality of conductive layers and the channel layer; and anti-ferroelectric patterns interposed between the plurality of interlayer insulating layers and the channel layer.

In accordance with another embodiment of the present disclosure is a method of manufacturing a ferroelectric memory device, the method including: forming a hole penetrating, in a vertical direction (a stacking direction), a stack structure in which first material layers and second material layers are alternately stacked; forming a first recess region by etching, to a depth in a horizontal direction perpendicular to the vertical direction, a sidewall of each of the second material layers exposed through the hole; forming a deoxidation layer in the first recess region; sequentially forming a ferroelectric base layer and a channel layer along a sidewall of the hole; forming, as ferroelectric patterns, some regions of the ferroelectric base layer, which are adjacent to the deoxidation layer by performing an annealing process; exposing sidewalls of the first material layers and the second material layers by etching the stack structure; forming a second recess region by removing each of the exposed second material layers and the deoxidation layer; and forming a conductive layer by filling a conductive material in the second recess region.

In accordance with still another embodiment of the present disclosure is a ferroelectric memory device including: a gate stack structure including a plurality of interlayer insulating layers and a plurality of conductive layers, which are alternately stacked; a channel layer extending in a vertical direction (the stacking direction) in the gate stack structure; ferroelectric patterns interposed between the plurality of conductive layers and the channel layer; anti-ferroelectric patterns interposed between the plurality of interlayer insulating layers and the channel layer; and a deoxidation layer in contact with one sidewall of each of the plurality of conductive layers.

In accordance with still another embodiment of the present disclosure is a method of manufacturing a ferroelectric memory device, the method including: forming a hole penetrating, in a vertical direction (a stacking direction), a stack structure in which first material layers and second material layers are alternately stacked; sequentially forming a ferroelectric base layer and a channel layer along a sidewall of the hole; exposing sidewalls of the first material layers and the second material layers by etching the stack structure; forming recess regions through which some regions of the ferroelectric base layer are exposed by removing the exposed second material layers; forming a deoxidation layer in contact with the some regions of the ferroelectric base layer along surfaces of the recess regions; forming, as ferroelectric patterns, adjacent regions including the some regions of the ferroelectric base layer, which are in contact with the deoxidation layer, by performing an annealing process; and forming conductive layers by filling the recess regions with a conductive material.

### BRIEF DESCRIPTION OF THE DRAWINGS

Example embodiments will now be described more fully hereinafter with reference to the accompanying drawings; however, they may be embodied in different forms and should not be construed as being limited to the embodiments set forth herein. Rather, these embodiments are provided so that this disclosure will be enabling to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a diagram illustrating a ferroelectric memory device in accordance with an embodiment of the present disclosure.

FIG. 2 is a diagram illustrating a hysteresis curve of ferroelectric random-access memory.

FIG. 3 is a sectional view illustrating a ferroelectric memory device in accordance with an embodiment of the present disclosure.

FIGS. 4A to 4G are sectional views illustrating a manufacturing method of the ferroelectric memory device in accordance with an embodiment of the present disclosure.

FIG. 5 is a sectional view illustrating a ferroelectric memory device in accordance with another embodiment of the present disclosure.

FIGS. 6A to 6D are sectional views illustrating a manufacturing method of the ferroelectric memory device in accordance with another embodiment of the present disclosure.

FIG. 7 is a diagram illustrating a Solid-State Drive (SSD) system to which the ferroelectric memory device of the present disclosure is applied.

### DETAILED DESCRIPTION

The specific structural or functional description disclosed herein is merely illustrative for the purpose of describing embodiments according to the concept of the present disclosure. Embodiments according to the concept of the present disclosure can be implemented in various forms, and should not be construed as being limited to the embodiments set forth herein.

Some embodiments of the present disclosure are directed to a ferroelectric memory device and a manufacturing method of the ferroelectric memory device, which can reduce or prevent an interference characteristic between adjacent memory cells.

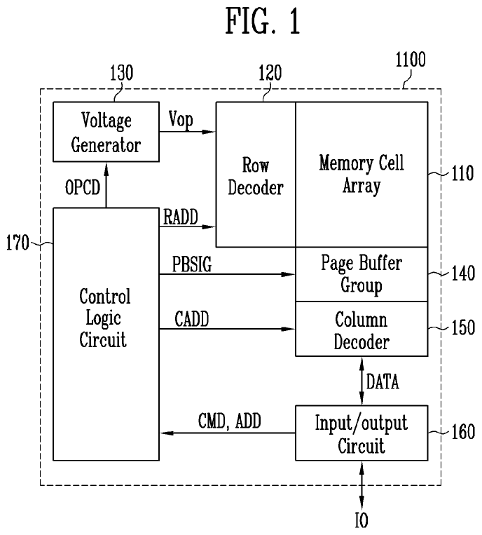

FIG. 1 is a diagram illustrating a ferroelectric memory device 1100 in accordance with an embodiment of the present disclosure.

Referring to FIG. 1, the ferroelectric memory device 1100 may include a memory cell array 110 in which data is stored and peripheral circuits 120 to 170 capable of performing a program, read, or erase operation.

The memory cell array 110 may include a plurality of memory blocks in which data is stored. Each of the memory blocks may include ferroelectric random-access memory cells, and the ferroelectric random-access memory cells may be implemented in a three-dimensional structure in which the ferroelectric random-access memory cells are stacked in a vertical direction above a substrate. The ferroelectric random-access memory cells may store data by using polarization varying according to a voltage applied to an electrode. Although the power supply may be interrupted, the ferroelectric random-access memory cells may retain stored data by means of a spontaneous polarization characteristic.

The peripheral circuits 120 to 170 may include a row decoder 120, a voltage generator 130, a page buffer group 140, a column decoder 150, an input/output circuit 160, and a control logic circuit 170.

The row decoder 120 may select one memory block among the memory blocks included in the memory cell array 110 according to a row address RADD, and transmit operating voltages Vop to the selected memory block.

The voltage generator 130 may generate and output operating voltages Vop necessary for various operations in response to an operation code OPCD.

The page buffer group 140 may be connected to the memory cell array 110 through bit lines. For example, the page buffer group 140 may include sensing circuits connected to the respective bit lines. The sensing circuits may simultaneously operate in response to sensing signals PBSIG, and temporarily store data in a program or read operation. The sensing circuits may sense a voltage or current of the bit lines, which varies according to a threshold voltage of the ferroelectric random-access memory cells, in a read or verify operation.

The column decoder 150 may transmit data DATA between the input/output circuit 160 and the page buffer group 140 according to a column address CADD.

The input/output circuit 160 may be connected to an external device through input/output lines IO. For example, the external device may be a controller capable of transmitting a command CMD, an address ADD, or data DATA to the ferroelectric memory device 1100. The input/output circuit 160 may input/output a command CMD, an address ADD, and data DATA through the input/output lines IO. For example, the input/output circuit 160 may transmit the command CMD and the address ADD, which are received from the external device, to the control logic circuit 170 through the input/output lines IO, and transmit the data DATA received from the external device to the column decoder 150 through the input/output lines IO. The input/output circuit 160 may output the data DATA received from the column decoder 150 to the external device through the input/output lines IO.

The control logic circuit 170 output the operation code OPCD, the row address RADD, the sensing signals PBSIG, and the column address CADD in response to the command CMD and the address ADD. For example, the control logic circuit 170 may include software configured to perform an algorithm in response to the command CMD and hardware configured to output the address ADD and various control signals.

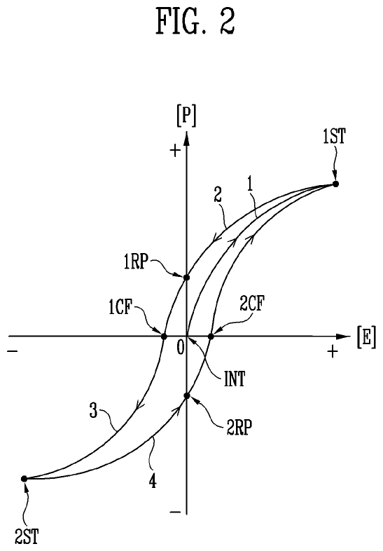

FIG. 2 is a diagram illustrating a hysteresis curve of a ferroelectric random-access memory.

Referring to FIG. 2, hysteresis is a phenomenon in which, when a material responds to an external stimulus, the material is influenced by not only an intensity of the external stimulus but also a current status or a past external stimulus history of the material. A hysteresis curve in a ferroelectric random-access memory represents a curve in which magnetization is changed according to the level of a voltage applied to an electrode, and this is also referred to as a ‘self-hysteresis curve.’

For example, polarization P becomes 0 in an initial status INT in which any voltage is not applied to the ferroelectric random-access memory (E=0). When a positive voltage is applied to the ferroelectric random-access memory in which the polarization P is 0, the polarization P increases (1), and therefore, the ferroelectric random-access memory may be in a saturation status. In this embodiment, the saturation status caused by the positive voltage is defined as a first saturation status 1ST. When the supply of the voltage to the ferroelectric random-access memory in the first saturation status 1ST is suspended, the polarization P decreases (2). The polarization P does not return to 0 as the initial status INT but may maintain a specific value. The polarization P is referred to as a remanent polarization. In this embodiment, the remanent polarization maintained after the first saturation status 1ST is defined as a first remanent polarization 1RP.

When a negative voltage is applied to the ferroelectric random-access memory in a first remanent polarization 1RP status, the polarization P again decreases. A voltage when the polarization P becomes 0 is referred to as a coercive field CF1. When a negative voltage lower than the coercive field CF1 is further applied to the ferroelectric random-access memory, the polarization P may further decreases (3), and the ferroelectric random-access memory may be in a second saturation status 2ST. Directions of positive and negative ions in the first saturation status 1ST and the second saturation status 2ST are opposite to each other. When the supply of the voltage higher than the coercive field CF2 to the ferroelectric random-access memory in the second saturation state 2ST is suspended, the polarization P again increases. The polarization P of the ferroelectric random-access memory may be maintained in a second remanent polarization 2RP status.

When a positive voltage is applied to the ferroelectric random-access memory in the second remanent polarization 2RP status, the polarization P again increases up to the first saturation status 1ST.

In the above-described manner, the polarization P of the ferroelectric random-access memory may vary according to the level of the voltage applied to the electrode. When any voltage is not applied, the polarization P of the ferroelectric random-access memory may be maintained at a constant level. The ferroelectric random-access memory may store data according to characteristics of the polarization P.

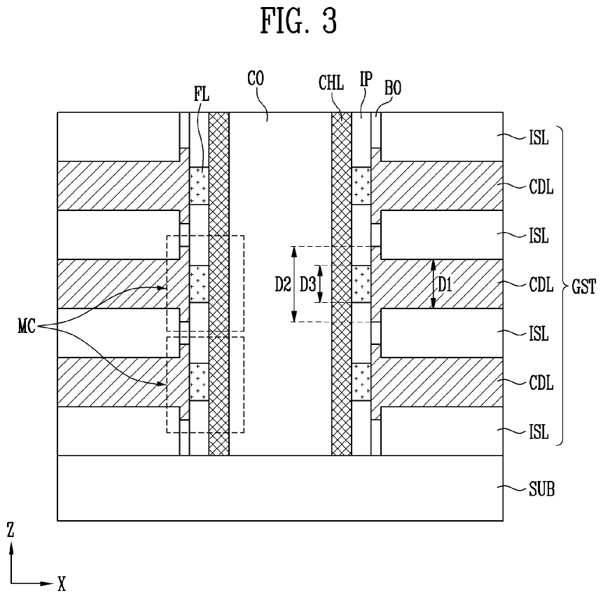

FIG. 3 is a sectional view illustrating a ferroelectric memory device in accordance with an embodiment of the present disclosure.

Referring to FIG. 3, the ferroelectric memory device may include memory blocks including ferroelectric random-access memory cells, and a portion of a memory string included in a memory block is illustrated in FIG. 3.

The string may include a plurality of ferroelectric random-access memory cells MC, and the plurality of ferroelectric random-access memory cells MC may be connected to conductive layers CDL corresponding to word lines. Each of the plurality of ferroelectric random-access memory cells MC may include a ferroelectric layer FL and a channel layer CHL, and an insulating pattern IP may be disposed between ferroelectric layers FL of respective ferroelectric random-access memory cells MC adjacent to each other.

Interlayer insulating layers ISL may be formed between the conductive layers CDL. The conductive layers CDL and the interlayer insulating layers ISL may constitute a gate stack structure GST. The conductive layers CDL and the interlayer insulating layers ISL may extend in an X direction which is a horizontal direction parallel to a substrate SUB. For example, the interlayer insulating layers ISL and the conductive layers CDL may be alternately stacked in a vertical direction on the top of a lower structure (not shown). The lower structure may include the substrate SUB and at least one of a source line, a source select line, and peripheral circuits, which are formed on the substrate SUB. The conductive layers CDL may be used as word lines and at least one select line. For example, when assuming that the interlayer insulating layers ISL and the conductive layers CDL are alternately stacked on the substrate SUB, the conductive layers CDL may include word lines and drain and source select lines. The interlayer insulating layers ISL may be formed of an oxide, and the conductive layers CDL may be formed of a metal such as tungsten.

The conductive layers CDL may extend farther toward the channel layer CHL than the interlayer insulating layers ISL. That is, the conductive layers CDL may protrude farther in the direction in which the conductive layers CDL are adjacent to the channel layer CHL as compared with the interlayer insulating layers ISL. A thickness D2 of a protrusion part of each the conductive layers CDL may be thicker than a thickness D1 of each of the conductive layers CDL interposed between the interlayer insulating layers ISL. That is, an end portion of each of the conductive layers CDL in the direction in which the conductive layers CDL are adjacent to the channel layer CHL may have a “T” shape.

The channel layer CHL may be formed while penetrating the gate stack structure GST in a Z direction which is a direction perpendicular to the substrate SUB. That is, the channel layer CHL may be formed in the gate stack structure GST to extend in the Z direction which is the direction perpendicular to the substrate SUB. The channel layer CHL may be used to allow a current to flow in the string. The channel layer CHL may be formed of poly-silicon.

Ferroelectric layers FL may be interposed between the channel layer CHL and the conductive layers CDL. The ferroelectric layers FL are made of a material which is electrically polarized by an external electric field but can maintain polarization even when the electric field is not applied from the outside. That the polarization is electrically maintained means that data is stored by maintaining different polarities. The ferroelectric layers FL may be formed of at least one material among PbZrTiO₃ (PSZ), SrBi₂Ta₂O₉ (STB), BiFeO₃ (BFO), HfO₂, HfO₂ZrO₂ (HZO), and HfSiO₄ (HSO). For example, the ferroelectric layers FL may be formed of any one layer among the above-described layers or be formed of a mixed layer of the above-described layers or a stacked layer of the above-described layers.

A thickness D3 of each of the ferroelectric layers FL may be thinner than the thickness D2 of the protrusion part of each of the adjacent conductive layers CDL.

An insulating pattern IP may be interposed between ferroelectric layers FL adjacent to each other in the vertical direction. The insulating pattern IP may be made of an anti-ferroelectric material. The insulating pattern IP may be defined as an anti-ferroelectric pattern.

A blocking layer BO may be interposed between the insulating pattern IP and the interlayer insulating layers ISL. The blocking layer BO may include a high dielectric constant material. For example, the blocking layer BO may include hafnium oxide (HfO₂).

A core insulating layer CO extending in the Z direction as the vertical direction may be interposed inside the channel layer CHL. The core insulating layer CO may include an oxide.

The ferroelectric layers FL and the insulating pattern IP may be formed using the same material. As compared with the insulating pattern IP, oxygen existing inside the ferroelectric layers FL may be removed. Accordingly, the ferroelectric layers FL may have a ferroelectric characteristic due to oxygen vacancies, and the insulating pattern IP may have an anti-ferroelectric characteristic.

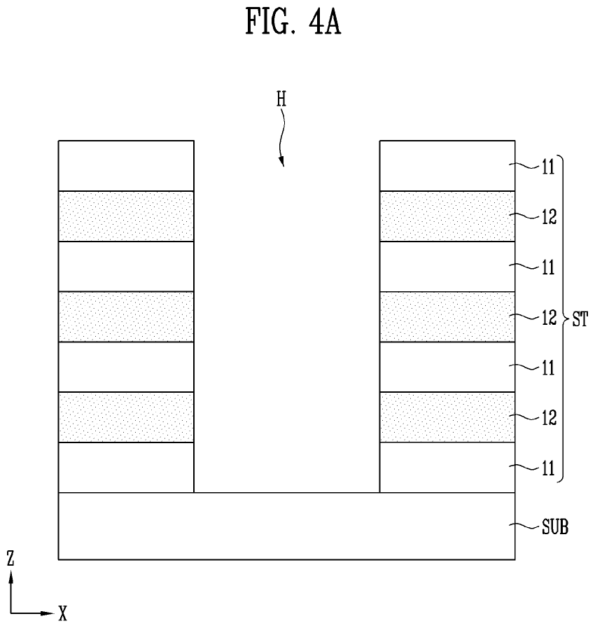

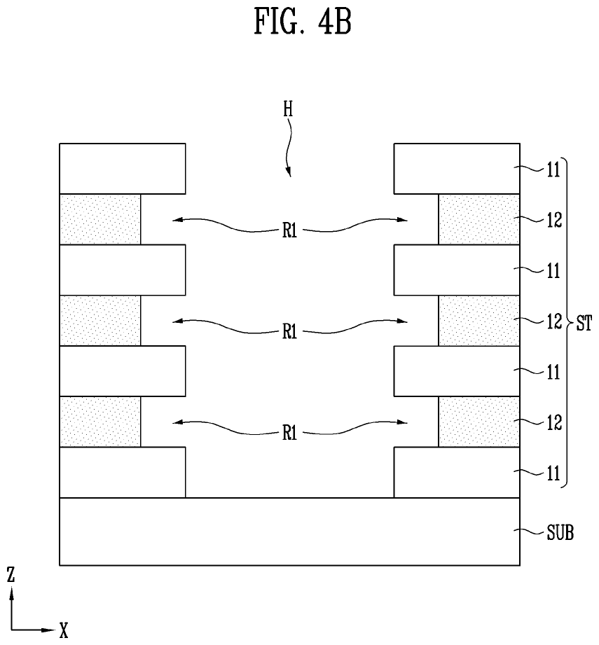

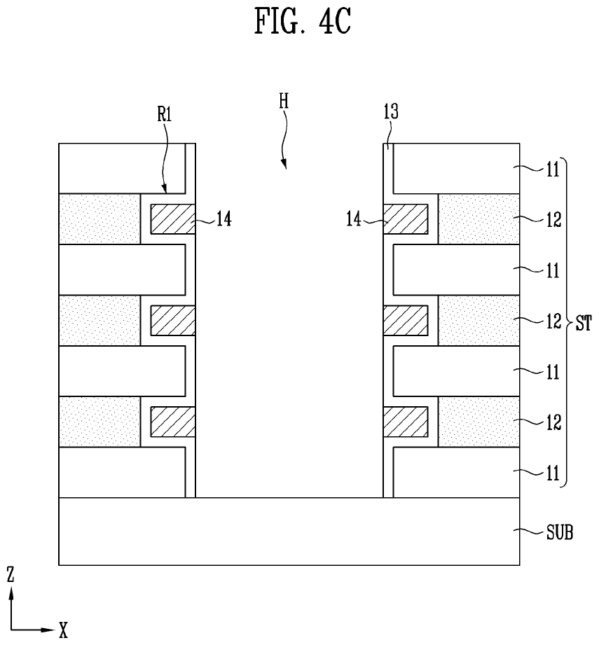

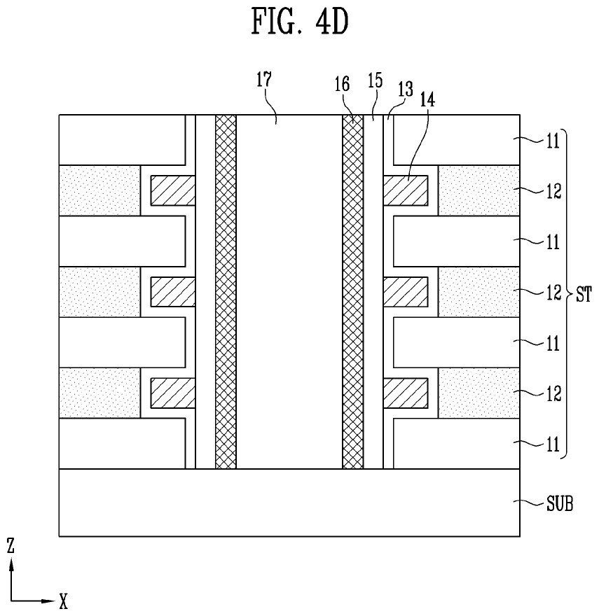

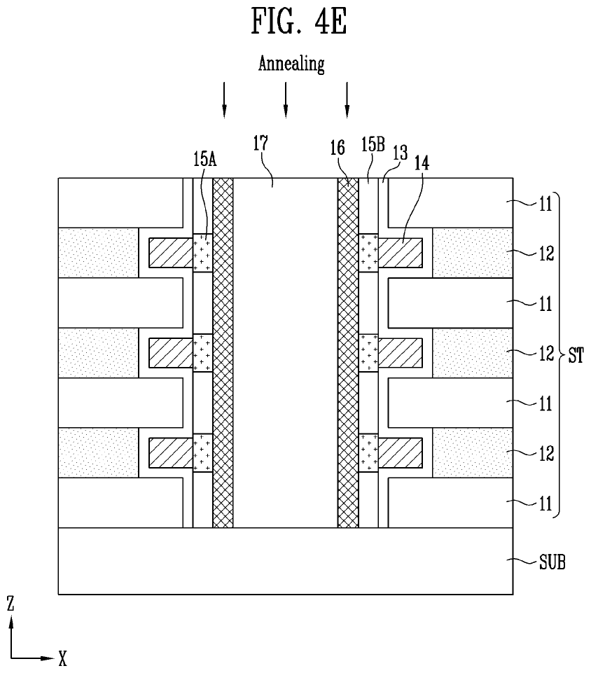

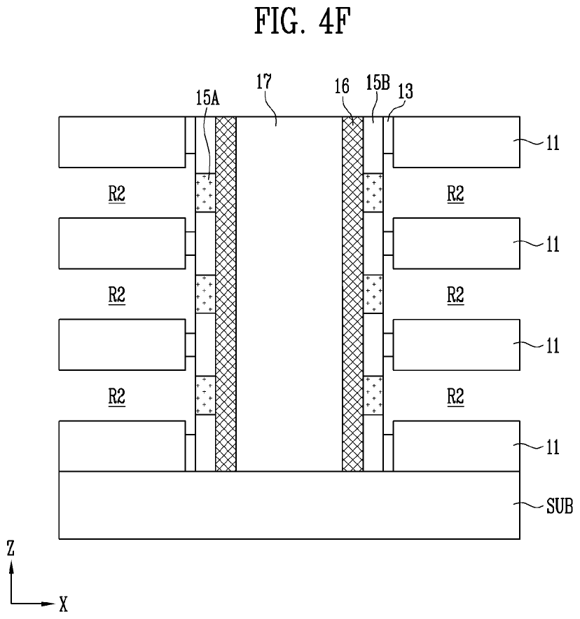

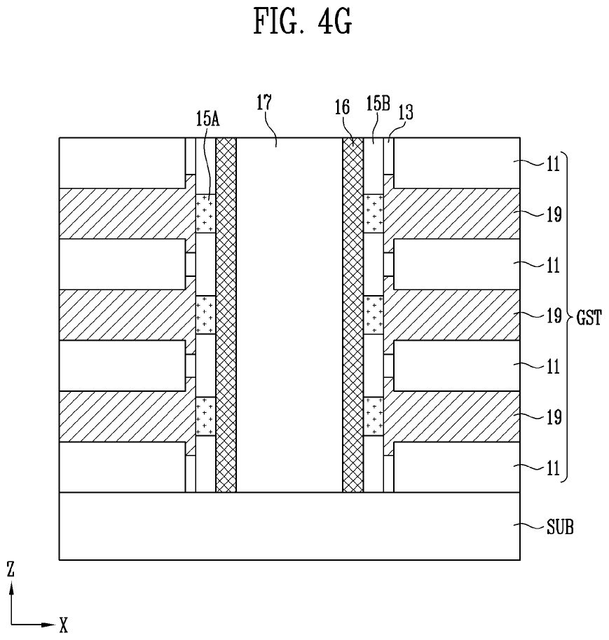

FIGS. 4A to 4G are sectional views illustrating a manufacturing method of the ferroelectric memory device in accordance with an embodiment of the present disclosure.

Referring to FIG. 4A, a stack structure ST is formed on a substrate SUB. The stack structure ST may include first material layers 11 and second material layers 12, which are alternately stacked. The first and second material layers 11 and 12 may be stacked in a direction perpendicular to the substrate SUB. The first and second material layers 11 and 12 may be formed using a deposition process such as Chemical Vapor Deposition (CVD).

The first material layers 11 may include a material having a high etch selectivity with respect to the second material layers 12. In an example, the first material layers 11 may include an insulating material such as an oxide, and the second material layers 12 may include a sacrificial material such as a nitride.

Subsequently, a hard mask pattern (not shown) may be formed on the stack structure ST, and a hole H penetrating at least a portion of the stack structure ST may be formed by performing an etching process, using the hard mask pattern. The hole H may partially extend to the inside of the substrate SUB.

Referring to FIG. 4B, first recess regions R1 are formed by etching the second material layers 12 exposed through the hole H to a certain depth in a direction horizontal to the substrate SUB. That is, sidewalls of the second material layers 12 etches to a certain depth such that the first material layers 11 further protrude in the horizontal direction as compared with the second material layers 12.

Referring to FIG. 4C, a blocking layer 13 is formed along a sidewall of the hole H. The blocking layer 13 may include hafnium oxide (HfO₂). The blocking layer 13 may be formed in a liner form along sidewalls of the first recess regions R1. For example, the blocking layer 13 may be formed along the sidewalls of the second material layers 12 and surfaces of the protruding first material layers 11. The blocking layer 13 may be formed by adjusting a thickness thereof such that the first recess regions R1 are not completely filled.

After that, a deoxidation layer 14 is formed such that the first recess regions R1 are completely filled. For example, after the deoxidation layer 14 is formed on a surface of the blocking layer 13 such that the first recess regions R1 are completely filled, the deoxidation layer 14 formed at the outside of the first recess regions R1 may be removed by performing an etching process. For example, the deoxidation layer 14 may include titanium (Ti) or poly-silicon. The deoxidation layer 14 may be formed of a material having a relatively high bonding force with oxygen.

Referring to FIG. 4D, a ferroelectric base layer 15 and a channel layer 16 are sequentially formed along the exposed surfaces of the blocking layer 13 and the deoxidation layer 14.

The ferroelectric base layer 15 may be formed of at least one material among PbZrTiO₃ (PSZ), SrBi2Ta₂O₉ (STB), BiFeO₃ (BFO), HfO₂, HfO₂ZrO₂ (HZO), and HfSiO₄ (HSO). For example, the ferroelectric base layer 15 may be formed of any one layer among the above-described layers or be formed of a mixed layer of the above-described layers or a stacked layer of the above-described layers. The ferroelectric base layer 15 is formed to be in direct contact with an outer wall of the deoxidation layer 14. Additionally, a dopant may be implanted into the ferroelectric base layer 15 by performing an ion implanting process, and the dopant may be Si.

The channel layer 16 may be formed of poly-silicon.

After that, a core insulating layer 17 may be formed such that the inside of the hole H is completely filled. The core insulating layer 17 may include an oxide layer.

Referring to FIG. 4E, some regions of the ferroelectric base layer (15 shown in FIG. 4D), which are adjacent to the deoxidation layer 14, are formed as ferroelectric patterns 15A by performing an annealing process. That is, the some regions of the ferroelectric base layer (15 shown in FIG. 4D), which are adjacent to the deoxidation layer 14, may be changed to the ferroelectric patterns 15A. For example, through the annealing process, oxygen in the some regions of the ferroelectric base layer (15 shown in FIG. 4D), which are adjacent to the deoxidation layer 14, is moved to the deoxidation layer 14 and then bonded to the deoxidation layer 14. Therefore, the oxygen in the some regions of the ferroelectric base layer (15 shown in FIG. 4D), which are adjacent to the deoxidation layer 14, may be removed. Accordingly, there may occur a difference between crystals in the some regions of the ferroelectric base layer (15 shown in FIG. 4D), which are adjacent to the deoxidation layer 14, and the other regions of the ferroelectric base layer (15 shown in FIG. 4D), which are not adjacent to the deoxidation layer 14. The ferroelectric base layer (15 shown in FIG. 4D) from which the oxygen is removed may have a ferroelectric characteristic due to oxygen vacancies, and regions including the oxygen vacancies may be defined as the ferroelectric patterns 15A. The other parts except the ferroelectric patterns 15A in the ferroelectric base layer (15 shown in FIG. 4D) may be anti-ferroelectric patterns having an anti-ferroelectric characteristic, and these portions may be defined as insulting patterns 15B.

Referring to FIG. 4F, an etching process is performed such that a sidewall of the stack structure (ST shown in FIG. 4E) is exposed, and the exposed second material layers (12 shown in FIG. 4E) are removed. Spaces from which the second material layers (12 shown in FIG. 4E) are removed may be defined as second recess regions R2.

Portions of the blocking layer 13, which are exposed through the second recess regions R2, are etched, thereby exposing the deoxidation layer (14 shown in FIG. 4E). After, the exposed deoxidation layer (14 shown in FIG. 4E) is removed. Accordingly, the ferroelectric patterns 15A may be exposed through the second recessed regions R2. Portions of the blocking layer 13 between the first material layers 11 and the insulating patterns 15B may remain.

Referring to FIG. 4G, conductive layers 19 are formed by filling the second recess regions (R2 shown in FIG. 4F) with a conductive material. The conductive layers 19 may include a conductive material such as poly-silicon, tungsten, or other metal.

A gate stack structure GST may be defined, including the first material layers 11 and the conductive layers 19.

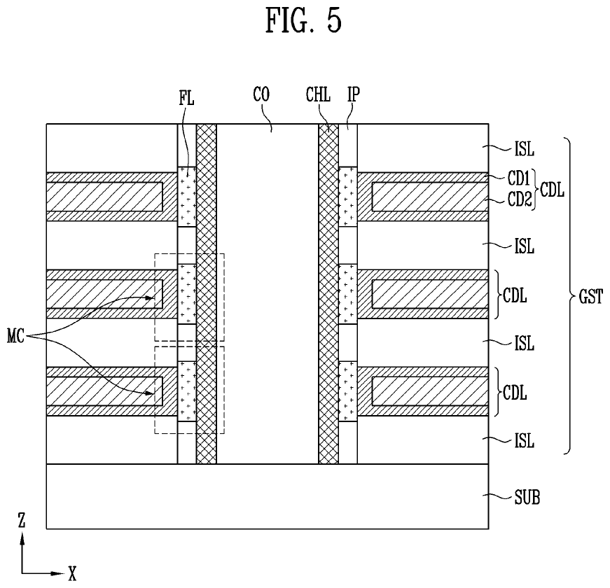

FIG. 5 is a sectional view illustrating a ferroelectric memory device in accordance with another embodiment of the present disclosure.

Referring to FIG. 5, the ferroelectric memory device may include memory blocks including ferroelectric random-access memory cells, and a portion of a memory string included in a memory block is illustrated in FIG. 5.

The string may include a plurality of ferroelectric random-access memory cells MC, and the plurality of ferroelectric random-access memory cells MC may be connected to conductive layers CDL corresponding to word lines. Each of the plurality of ferroelectric random-access memory cells MC may include a ferroelectric layer FL and a channel layer CHL, and an insulating pattern IP may be disposed between ferroelectric layers FL of respective ferroelectric random-access memory cells MC adjacent to each other. The insulating pattern IP may be defined as an anti-ferroelectric pattern.

Interlayer insulating layers ISL may be formed between the conductive layers CDL. The conductive layers CDL and the interlayer insulating layers ISL may constitute a gate stack structure GST. The conductive layers CDL and the interlayer insulating layers ISL may extend in an X direction which is a horizontal direction parallel to a substrate SUB. For example, the interlayer insulating layers ISL and the conductive layers CDL may be alternately stacked on the top of a lower structure (not shown). The lower structure may include the substrate SUB and at least one of a source line, a source select line, and peripheral circuits, which are formed on the substrate SUB. The conductive layers CDL may be used as word lines and at least one select line. For example, when assuming that the interlayer insulating layers ISL and the conductive layers CDL are alternately stacked on the substrate SUB, the conductive layers CDL may include word lines and drain and source select lines. The interlayer insulating layers ISL may be formed of an oxide.

Each of the conductive layers CDL may include a first conductive layer CD1 and a second conductive layer CD2. The first conductive layer CD1 may be formed to surround one sidewall, an upper surface, and a lower surface of the second conductive layer CD2. The first conductive layer CD1 may be a deoxidation layer. The first conductive layer CD1 may be formed of a material having a strong oxygen bonding force, such as titanium. The second conductive layer CD2 may be formed of a metal such as tungsten.

The channel layer CHL may be formed while penetrating the gate stack structure GST in a Z direction which is a direction perpendicular to the substrate SUB. That is, the channel layer CHL may be formed in the gate stack structure GST to extend in the Z direction which is the direction perpendicular to the substrate SUB. The channel layer CHL may be used to allow a current to flow in the string. The channel layer CHL may be formed of poly-silicon.

Ferroelectric layers FL may be interposed between the channel layer CHL and the conductive layers CDL. The ferroelectric layers FL are made of a material which is electrically polarized by an external electric field but can maintain polarization even when the electric field is not applied from the outside. That the polarization is electrically maintained means that data is stored by maintaining different polarities. The ferroelectric layers FL may be formed of at least one material among PbZrTiO₃ (PSZ), SrBi2Ta₂O₉ (STB), BiFeO₃ (BFO), HfO₂, HfO₂ZrO₂ (HZO), and HfSiO₄ (HSO). For example, the ferroelectric layers FL may be formed of any one layer among the above-described layers or be formed of a mixed layer of the above-described layers or a stacked layer of the above-described layers.

An insulating pattern IP may be interposed between ferroelectric layers FL adjacent to each other in the vertical direction. The insulating pattern IP may be made of an anti-ferroelectric material or a high dielectric constant material.

A core insulating layer CO extending in the Z direction as the vertical direction may be interposed inside the channel layer CHL. The core insulating layer CO may include an oxide.

The ferroelectric layers FL and the insulating pattern IP may be formed using the same material. As compared with the insulating pattern IP, oxygen existing inside the ferroelectric layers FL may be removed. Accordingly, the ferroelectric layers FL may have a ferroelectric characteristic due to oxygen vacancies, and the insulating pattern IP may have an anti-ferroelectric characteristic.

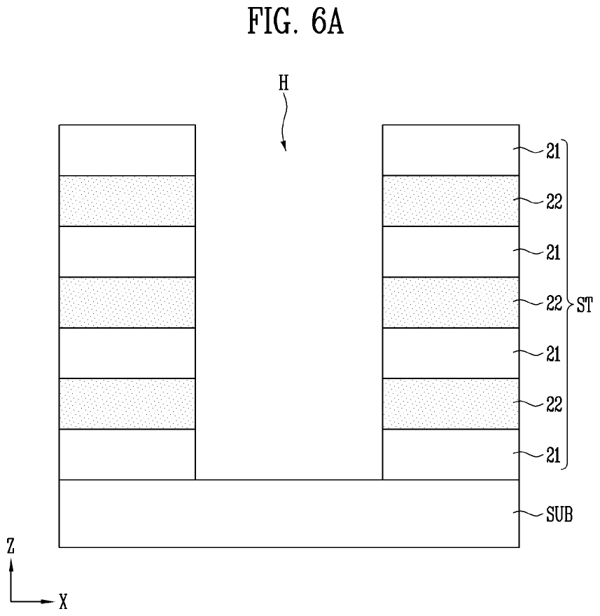

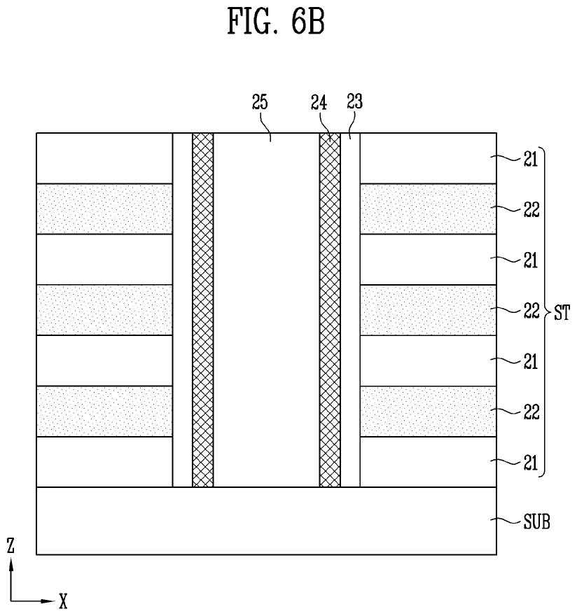

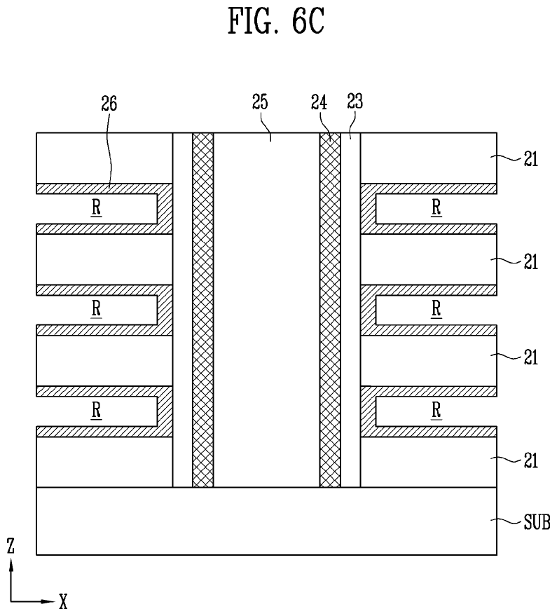

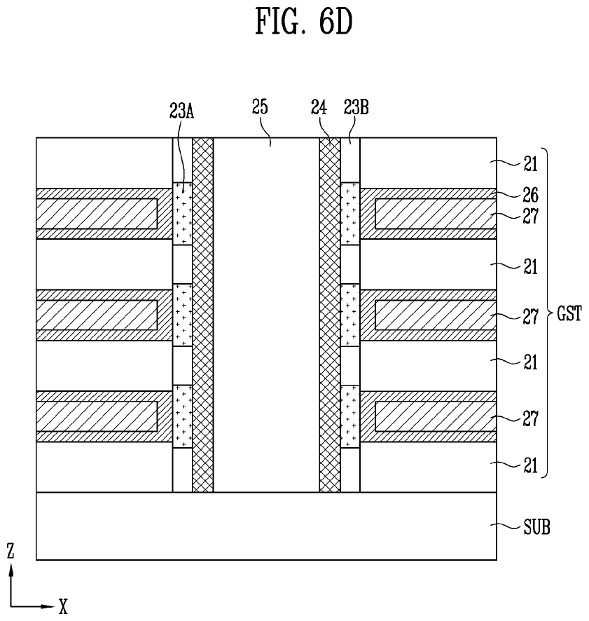

FIGS. 6A to 6D are sectional views illustrating a manufacturing method of the ferroelectric memory device in accordance with another embodiment of the present disclosure.

Referring to FIG. 6A, a stack structure ST is formed on a substrate SUB. The stack structure ST may include first material layers 21 and second material layers 22, which are alternately stacked. The first and second material layers 21 and 22 may be stacked in a direction perpendicular to the substrate SUB. The first and second material layers 21 and 22 may be formed using a deposition process such as Chemical Vapor Deposition (CVD).

The first material layers 21 may include a material having a high etch selectivity with respect to the second material layers 22. In an example, the first material layers 21 may include an insulating material such as an oxide, and the second material layers 22 may include a sacrificial material such as a nitride.

Subsequently, a hard mask pattern (not shown) may be formed on the stack structure ST, and a hole H penetrating at least a portion of the stack structure ST may be formed by performing an etching process, using the hard mask pattern. The hole H may partially extend to the inside of the substrate SUB.

Referring to FIG. 6B, a ferroelectric base layer 23 and a channel layer 24 are sequentially formed along a sidewall of the hole H.

The ferroelectric base layer 23 may be formed of at least one material among PbZrTiO₃ (PSZ), SrBi2Ta₂O₉ (STB), BiFeO₃ (BFO), HfO₂, HfO₂ZrO₂ (HZO), and HfSiO₄ (HSO). For example, the ferroelectric base layer 23 may be formed of any one layer among the above-described layers or be formed of a mixed layer of the above-described layers or a stacked layer of the above-described layers. Additionally, a dopant may be implanted into the ferroelectric base layer 23 by performing an ion implanting process, and the dopant may be Si.

The channel layer 24 may be formed of poly-silicon.

After that, a core insulating layer 25 may be formed such that the inside of the hole H is completely filled. The core insulating layer 25 may include an oxide layer.

Referring to FIG. 6C, an etching process is performed such that a sidewall of the stack structure (ST shown in FIG. 6B) is exposed, and the exposed second material layers (22 shown in FIG. 6B) are removed. Spaces in which the second material layers (22 shown in FIG. 6B) are removed may be defined as recess regions R.

After that, a deoxidation layer 26 is formed along some sidewalls of the ferroelectric base layer 23 and upper surfaces and lower surfaces of the first material layers 21, which are exposed through the recess regions R. The deoxidation layer 26 may include titanium (Ti) or poly-silicon. The deoxidation layer 26 may be formed of a material having a relatively high bonding force with oxygen. The deoxidation layer 26 may be used as a conductive layer for word lines.

Referring to FIG. 6D, some regions of the ferroelectric base layer (23 shown in FIG. 6C), which are adjacent to the deoxidation layer 26, are formed as ferroelectric patterns 23A by performing an annealing process.

For example, through the annealing process, oxygen in the some regions of the ferroelectric base layer (23 shown in FIG. 6C), which are adjacent to the deoxidation layer 26, is moved to the deoxidation layer 26 and then bonded to the deoxidation layer 26. Therefore, the oxygen in the some regions of the ferroelectric base layer (23 shown in FIG. 6C), which are adjacent to the deoxidation layer 26, may be removed. Accordingly, there may occur a difference between crystals in the some regions of the ferroelectric base layer (23 shown in FIG. 6C), which are adjacent to the deoxidation layer 26, and the other regions of the ferroelectric base layer (23 shown in FIG. 6C), which are not adjacent to the deoxidation layer 26. The ferroelectric base layer (23 shown in FIG. 6C) from which the oxygen is removed may have a ferroelectric characteristic due to oxygen vacancies, and regions including the oxygen vacancies may be defined as the ferroelectric patterns 23A. The other parts except the ferroelectric patterns 23A in the ferroelectric base layer (23 shown in FIG. 6C) may be anti-ferroelectric patterns having an anti-ferroelectric characteristic, and these portions may be defined as insulting patterns 23B.

After that, conductive layers 27 are formed by filling the recess regions (R shown in FIG. 6C) with a conductive material. The conductive layers 27 may include a conductive material such as poly-silicon, tungsten or metal. Accordingly, the deoxidation layer 26 may be formed to one sidewall, an upper surface, and a lower surface of each of the conductive layers 27.

A gate stack structure GST may be defined, including the first material layers 21, the deoxidation layer 26, and the conductive layers 27.

In another embodiment, after the deoxidation layer 26 is removed before the conductive layers 27 are formed, the conductive layers 27 may be formed.

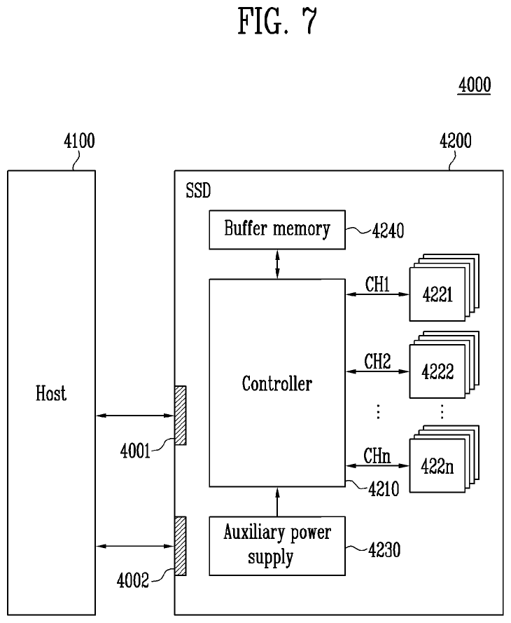

FIG. 7 is a diagram illustrating a Solid-State Drive (SSD) system 4000 to which the ferroelectric memory device of the present disclosure is applied.

Referring to FIG. 7, the SSD system 4000 includes a host 4100 and an SSD 4200. The SSD 4200 may exchange a signal with the host 4100 through a signal connector 4001, and be supplied with power through a power connector 4002. The SSD 4200 includes a controller 4210, a plurality of ferroelectric memory devices 4221 to 422n, an auxiliary power supply 4230, and a buffer memory 4240.

In accordance with an embodiment of the present disclosure, each of the plurality of ferroelectric memory devices 4221 to 422n may be configured identically to the ferroelectric memory device 1100 described with reference to FIG. 1.

The controller 4210 may control the plurality of ferroelectric memory devices 4221 to 422n in response to a signal received from the host 4100. Exemplarily, the signal may be transmitted based on an interface between the host 4100 and the SSD 4200. For example, the signal may be defined by at least one of interfaces such as a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (PATA), a Small Computer System Interface (SCSI), an Enhanced Small Disk Interface (ESDI), an Integrated Drive Electronics (IDE), a firewire, a Universal Flash Storage (UFS), a WI-FI, a Bluetooth, and an NVMe.

The auxiliary power supply 4230 may be connected to the host 4100 through the power connector 4002. The auxiliary power supply 4230 may receive power input from the host 4100. When the supply of power from the host 4100 is not smooth, the auxiliary power supply 4230 may provide power to the SSD 4200. Exemplarily, the auxiliary power supply 4230 may be located in the SSD 4200, or be located at the outside of the SSD 4200. For example, the auxiliary power supply 4230 may be located on a main board, and provide auxiliary power to the SSD 4200.

The buffer memory 4240 may be used as buffer memory of the SSD 4200. For example, the buffer memory 4240 may temporarily store data received from the host 4100 or data received from the plurality of ferroelectric memory devices 4221 to 422n, or temporarily store metadata (e.g., a mapping table) of the plurality of ferroelectric memory devices 4221 to 422n. The buffer memory 4240 may include volatile memory such as DRAM, SDRAM, DDR SDRAM, LPDDR SDRAM, and GRAM or nonvolatile memory such as FRAM, ReRAM, STT-MRAM, and PRAM.

In accordance with the present disclosure, ferroelectric patterns of respective memory cells adjacent to each other are separated from each other by anti-ferroelectric patterns, so that an interference characteristic between memory cells can be reduced or prevented.

While the present disclosure has been shown and described with reference to certain embodiments thereof, it will be understood by those skilled in the art that various changes in form and detail may be made therein without departing from the spirit and scope of the present disclosure as defined by the appended claims and their equivalents. Therefore, the scope of the present disclosure should not be limited to the above-described embodiments but should be determined by not only the appended claims but also the equivalents thereof.

In the above-described embodiments, all steps may be selectively performed or some of the steps may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

Meanwhile, the embodiments of the present disclosure have been described in the drawings and specification. Although specific terminologies are used here, those are only to explain the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein.

What is claimed is:

1. A ferroelectric memory device comprising:
a gate stack structure including a plurality of interlayer insulating layers and a plurality of conductive layers, which are alternately stacked;
a channel layer extending in a vertical direction (the stacking direction) in the gate stack structure;
ferroelectric patterns interposed between the plurality of conductive layers and the channel layer; and
anti-ferroelectric patterns interposed between the plurality of interlayer insulating layers and the channel layer.

2. The ferroelectric memory device of claim 1, wherein the ferroelectric patterns and the anti-ferroelectric patterns include the same material, and wherein the ferroelectric patterns include oxygen vacancies.

3. The ferroelectric memory device of claim 1, wherein each of the anti-ferroelectric patterns is interposed between the ferroelectric patterns adjacent to each other in the vertical direction.

4. The ferroelectric memory device of claim 1, further including a blocking layer interposed between the plurality of interlayer insulating layers and the anti-ferroelectric patterns.

5. The ferroelectric memory device of claim 1, wherein each of the plurality of conductive layers includes a protrusion part protruding farther toward the channel layer than the plurality of interlayer insulating layers.

6. The ferroelectric memory device of claim 5, wherein a thickness of the protrusion part of each of the plurality of conductive layers is thicker in the vertical direction than a thickness in the vertical direction of the other part of each of the plurality of conductive layers interposed between the plurality of interlayer insulating layers.

7. The ferroelectric memory device of claim 5, wherein a thickness in the vertical direction of each of the ferroelectric patterns is thinner than the thickness in the vertical direction of the protrusion part.

8. The ferroelectric memory device of claim 1, wherein an end portion of each of the plurality of conductive layers in a direction toward the channel layer has a “T” shape.

9. A method of manufacturing a ferroelectric memory device, the method comprising:
forming a hole penetrating, in a vertical direction (a stacking direction), a stack structure in which first material layers and second material layers are alternately stacked;
forming a first recess region by etching, to a depth in a horizontal direction perpendicular to the vertical direction, a sidewall of each of the second material layers exposed through the hole;
forming a deoxidation layer in the first recess region;
sequentially forming a ferroelectric base layer and a channel layer along a sidewall of the hole;
forming, as ferroelectric patterns, some regions of the ferroelectric base layer, which are adjacent to the deoxidation layer by performing an annealing process;
exposing sidewalls of the first material layers and the second material layers by etching the stack structure;
forming a second recess region by removing each of the exposed second material layers and the deoxidation layer; and
forming a conductive layer by filling a conductive material in the second recess region.

10. The method of claim 9, wherein performing the annealing process comprises forming in the some regions of the ferroelectric base layer, which are adjacent to the deoxidation layer, oxygen vacancies by removing oxygen through the deoxidation layer.

11. The method of claim 9, wherein, in the annealing process, the other regions of the ferroelectric base layer except the some regions of the ferroelectric base layer have an anti-ferroelectric characteristic.

12. The method of claim 9, wherein the deoxidation layer includes titanium (Ti) or poly-silicon.

13. The method of claim 9, further comprising forming a blocking layer along the sidewall of the hole before the forming of the deoxidation layer.

14. A ferroelectric memory device comprising:
a gate stack structure including a plurality of interlayer insulating layers and a plurality of conductive layers, which are alternately stacked;
a channel layer extending in a vertical direction (the stacking direction) in the gate stack structure;
ferroelectric patterns interposed between the plurality of conductive layers and the channel layer;
anti-ferroelectric patterns interposed between the plurality of interlayer insulating layers and the channel layer; and
a deoxidation layer in contact with one sidewall of each of the plurality of conductive layers.

15. The ferroelectric memory device of claim 14, wherein the deoxidation layer surrounds an upper surface and a lower surface of each of the plurality of conductive layers.

16. The ferroelectric memory device of claim 14, wherein the deoxidation layer includes titanium (Ti) or poly-silicon.

17. The ferroelectric memory device of claim 14, wherein the ferroelectric patterns and the anti-ferroelectric patterns include the same material, and wherein the ferroelectric patterns include oxygen vacancies.

18. The ferroelectric memory device of claim 14, wherein each of the anti-ferroelectric patterns is interposed between the ferroelectric patterns adjacent to each other in the vertical direction.

19. A method of manufacturing a ferroelectric memory device, the method comprising:
forming a hole penetrating, in a vertical direction (a stacking direction), a stack structure in which first material layers and second material layers are alternately stacked;
sequentially forming a ferroelectric base layer and a channel layer along a sidewall of the hole;
exposing sidewalls of the first material layers and the second material layers by etching the stack structure;
forming recess regions through which some regions of the ferroelectric base layer are exposed by removing the exposed second material layers;
forming a deoxidation layer in contact with the some regions of the ferroelectric base layer along surfaces of the recess regions;
forming, as ferroelectric patterns, adjacent regions including the some regions of the ferroelectric base layer, which are in contact with the deoxidation layer, by performing an annealing process; and
forming conductive layers by filling the recess regions with a conductive material.

20. The method of claim 19, wherein performing the annealing process comprises forming oxygen vacancies by removing oxygen through the deoxidation layer from the adjacent regions including the some regions of the ferroelectric base layer, which are in contact with the deoxidation layer.

21. The method of claim 19, wherein, in the annealing process, the other regions of the ferroelectric base layer except the adjacent regions of the ferroelectric base layer have an anti-ferroelectric characteristic.

22. The method of claim 19, wherein the deoxidation layer includes titanium (Ti) or poly-silicon.
